(19) United States
(12) Patent Application Publication
(10) Pub. No.: US 2024/0035198 A1
(43) Pub. Date: Feb. 1, 2024

(54) SYSTEMS AND METHODS FOR FORMING SINGLE CRYSTAL SILICON INGOTS WITH CRUCIBLES HAVING A SYNTHETIC LINER

(71) Applicant: GlobalWafers Co., Ltd., Hsinchu (TW)

(72) Inventor: Richard Joseph Phillips, St. Peters, MO (US)

(21) Appl. No.: 18/356,380

(22) Filed: Jul. 21, 2023

Related U.S. Application Data
(60) Provisional application No. 63/369,786, filed on Jul. 29, 2022.

(51) Int. Cl. C30B 29/06; C30B 15/10; C30B 15/04

(52) U.S. Cl. CPC C30B 29/06; C30B 15/10; C30B 15/04

(57) ABSTRACT

A method for producing a single crystal silicon ingot from a silicon melt includes providing a crucible within an inner chamber of an ingot puller, the crucible including an inner surface and a synthetic liner on the inner surface. The method further includes adding an initial charge of polysilicon to the crucible, melting the initial charge of polysilicon to cause the silicon melt to form in the crucible, and dissolving a melt modifier into the silicon melt to devitrify the synthetic liner and form a crystallized layer on the crucible. The crystallized layer has a thickness less than 700 microns. The method further includes pulling a single crystal silicon ingot from the silicon melt.

### CROSS-REFERENCE TO RELATED APPLICATION

This application claims priority to U.S. Provisional Patent Application No. 63/369,786 filed on Jul. 29, 2022, the entire disclosure of which is hereby incorporated by reference in its entirety.

### FIELD

The field relates to systems and methods for forming single crystal ingots with crucibles having a synthetic liner and, in particular, systems and methods for forming single crystal silicon ingots by the Czochralski or Continuous Czochralski processes, in which the synthetic liner is used in combination with a melt modifier for promoting devitrification of the liner.

### BACKGROUND

Single crystal silicon, which is the starting material for most processes for the fabrication of many electronic components such as semiconductor devices and solar cells, is commonly prepared by the Czochralski (CZ) or Continuous Czochralski (CCZ) methods. In these methods, a polycrystalline source material, such as polycrystalline silicon (“polysilicon”), in the form of solid feedstock material is charged to a quartz crucible and melted, a single seed crystal is brought into contact with the molten silicon or melt, and a single crystal silicon ingot is grown by slow extraction.

The quartz crucible includes an inner surface which defines a cavity for receiving the melt. Some crucibles include a vitreous silica liner with a coating applied on the inner surfaces. Such liners can be designed to undergo a devitrification process at high temperatures, which causes the liners to crystalize, thereby becoming cristobalite rather than vitreous silica and forming a crystallized layer on the crucible. The devitrification of the liner provides the heated crucible sidewall with an enhanced stiffness and reduces reactions between the melt and the crucible that can induce vibrations in the silicon melt and negatively affect the resulting ingot. Synthetic silica or natural silica liners may be used.

Synthetic silica liners have an advantage of containing lower impurities relative to natural silica liners, thereby reducing the potential for contamination of the melt. However, one problem with synthetic liners in crucibles is that the devitrification process results in random nucleation on the synthetic liner and as these nuclei grow, the resulting devitrification is also random. This causes the surface presented to the melt to be a mixed structure, one of a glassy nature as well as a crystallized nature. As a result of the mixed surface, synthetic lined crucibles, absent other modifications, must be operated in shorter intervals to limit the length of exposure to the melt, also referred to as “hot hours.” Additionally, absent modification, the resulting crystallized layers have an increased surface roughness, causing increased bubble nucleation in the melt which can damage the ingot.

Devitrifying agents or nucleating agents (terms used interchangeably herein), such as Barium (Ba), Calcium (Ca), or Strontium (Sr), may be coated on the synthetic liners to promote devitrification of the synthetic liners. However, once nucleated by such agents, the devitrification of the liners proceeds much faster relative to natural liners and results in increased thickness of the crystallized layer. For example, some such crystallized layers that are produced from a synthetic liner coated with a nucleating agent have a thickness that is increased by a factor of five or greater relative to natural liners for the same concentration of nucleating agents. As an example, a typical devitrified synthetic liner on a crucible has a thickness of about 2 millimeters (mm).

The increased thickness of synthetic devitrified liners relative to natural liners reduces the structural stability of the devitrified layer during use. For example, during ingot growth, the devitrified layer is thermally cycled over a large temperature range from around 1100 degrees Celsius to 1500 degrees Celsius, producing a temperature differential at different sections along the thickness of the liner and inducing strain in the liner. If the strain becomes sufficiently large, thermal spalling occurs and portions of the liner crack off into the melt, providing a potential source of particulates in the melt and potentially resulting in defects in the crystal ingot. Additionally, because the synthetic liner is thickened relative to natural liners, it may drift towards and contact a meniscus of the growing ingot before melting. If the unmelted portion of the liner contacts the meniscus, a loss of zero dislocation structure results and the single crystal dislocates and a polycrystalline material results, thereby rendering the crystal inoperable for use in device applications.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for producing a single crystal silicon ingot from a silicon melt held within a crucible positioned within an ingot puller apparatus. The method includes providing a crucible within an inner chamber of an ingot puller, the crucible including an inner surface and a synthetic liner on the inner surface. The method further includes adding an initial charge of polysilicon to the crucible, melting the initial charge of polysilicon to cause the silicon melt to form in the crucible, and dissolving a melt modifier into the silicon melt to devitrify the synthetic liner and form a crystallized layer on the crucible. The crystallized layer has a thickness less than 700 microns. The method further includes pulling a single crystal silicon ingot from the silicon melt.

Another aspect of the present disclosure is directed to a crucible for use with an ingot puller apparatus. The crucible includes a body having an inner surface and an opposed outer surface and a synthetic liner provided on the inner surface of the body. The synthetic liner has a composition that devitrifies when exposed to a silicon melt to form a crystallized layer on the crucible during a crystal growing operation. The crystallized layer has a thickness less than 700 microns.

Another aspect of the present disclosure is directed to a method for producing a single crystal silicon ingot from a silicon melt held within a crucible positioned within an ingot puller apparatus. The method includes providing the crucible within an inner chamber of the ingot puller, the crucible including an inner surface and a synthetic liner on the inner surface. The method further includes adding an initial charge of polysilicon to the crucible and adding a melt modifier precursor to the crucible. The method further includes melting the initial charge of polysilicon to cause the silicon melt to form in the crucible and dissolving the melt modifier precursor in the silicon melt to release a concentration of melt modifier into the silicon melt. The concentration of melt modifier devitrifies the synthetic liner and forms a crystallized layer on the crucible. The crystallized layer has a thickness less than 700 microns.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a schematic of a pulling apparatus for forming a single crystal silicon ingot;

FIG. 2 is a schematic sectional view of a crucible of the pulling apparatus shown in FIG. 1 having a melt therein;

FIG. 3 is a schematic sectional view of a region A of the crucible shown in FIG. 2, showing a liner of the crucible prior to devitrification;

FIG. 4 is a schematic sectional view of the region of the crucible shown in FIG. 3, showing a crystallized layer formed on the crucible from the devitrification of the liner shown in FIG. 3;

FIG. 5 shows results of surface roughness testing for a first lined crucible sample immersed in a control silicon melt and a second lined crucible sample immersed in a doped silicon melt;

FIG. 6 shows microscopic images taken of the first and second lined crucible samples after immersion in the respective melts; and

FIG. 7 is a flow diagram of a method for producing a single crystal silicon ingot from a silicon melt held within a crucible positioned within an ingot puller apparatus.

Corresponding reference characters indicate corresponding parts throughout the drawings.

### DETAILED DESCRIPTION

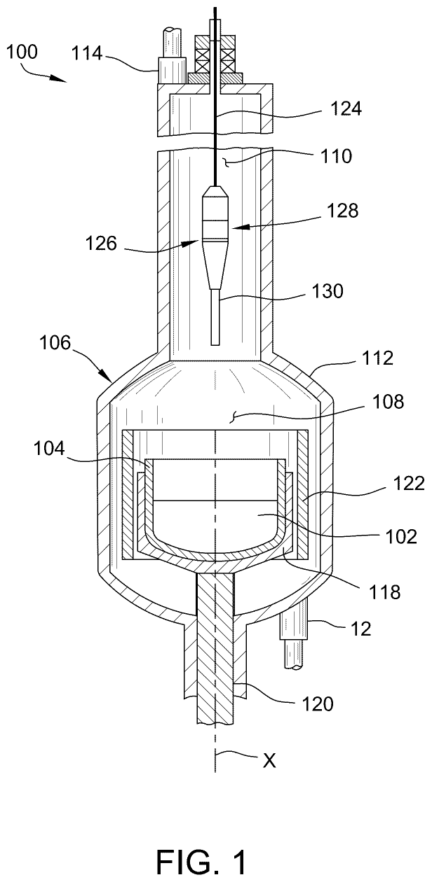

Referring to FIG. 1, an ingot pulling apparatus or ingot puller is shown schematically and is indicated generally at 100. The ingot puller 100 is used to produce single crystal (i.e., monocrystalline) ingots of semiconductor or solar-grade material such as, for example, single crystal silicon ingots. The example ingot is grown by the so-called Czochralski (CZ) process in which the ingot is withdrawn from a silicon melt 102 held within a crucible 104 of crystal puller 100. The ingot may also be grown by the batch CZ process in which polycrystalline silicon is charged to the crucible 104 in an amount sufficient to grow one ingot, such that the crucible 104 is essentially depleted of silicon melt 102 after the growth of the one ingot. In other embodiments, the ingot may be grown by the Continuous CZ (CCZ) process in which polycrystalline silicon is continually or periodically added to crucible 104 to replenish silicon melt 102 during the growth process. The CCZ process facilitates growth of multiple ingots pulled from a single crucible 104.

The ingot puller 100 includes a housing 106 that defines a crystal growth chamber 108 and a pull chamber 110 having a smaller transverse dimension than the growth chamber 108. The growth chamber 108 has a generally dome shaped upper wall 112 transitioning from the growth chamber 108 to the narrowed pull chamber 110. The ingot puller 100 includes an inlet port 114 and an outlet port 116 which may be used to introduce and remove a process gas to and from the housing 106 during crystal growth.

The crucible 104 within the ingot puller 100 contains the silicon melt 102 from which a silicon ingot is drawn. The crucible 104 is suitably made of quartz or fused silica, which have a high degree of thermal stability, and are generally non-reactive with molten silicon in melt 102, although some slow dissolution of the crucible into the melt can occur. The crucible 104 may alternatively be made from other materials in addition to quartz. For example, the quartz crucible 104 may be made from a composite material that includes silica and an additional material, such as silicon nitride or silicon carbide. For example, in some applications, such as solar grade wafers or polycrystalline ingots, crucibles formed of such composite materials may be used.

The silicon melt 102 is obtained by melting polycrystalline silicon charged to the crucible 104. A feed system (not shown) is used for feeding solid feedstock material into the crucible assembly 104 and/or the melt 102. The crucible 104 is positioned within and supported by a susceptor 118 that is in turn supported by a rotatable shaft 120. Susceptor 118 and rotatable shaft 120 facilitate rotation of the crucible 104 about a central longitudinal axis X of the ingot puller 100.

A heating system 122 (e.g., an electrical resistance heater 122) surrounds the susceptor 118 and crucible 104 and supplies heat by conduction through the susceptor 118 and crucible 104 for melting the silicon charge to produce the melt 102 and/or maintaining the melt 102 in a molten state. The heater 122 may also extend below the susceptor 118 and crucible 104. The heater 122 is controlled by a control system (not shown) so that the temperature of the melt 102 is precisely controlled throughout the pulling process. For example, the controller may control electric current provided to heater 122 to control the amount of thermal energy supplied by heater 122. The controller may control heater 122 so that the temperature of the melt 102 is maintained above about the melting temperature of silicon (e.g., about 1412° C.). For example, the melt 102 may be heated to a temperature of at least about 1425° C., at least about 1450° C. or even at least about 1500° C. Insulation (not shown) surrounding the heater 122 may reduce the amount of heat lost through the housing 106. The ingot puller 100 may also include a heat shield assembly (not shown) above the surface of melt 102 for shielding the ingot from the heat of the crucible 104 to increase the axial temperature gradient at the solid-melt interface.

A pulling mechanism (not shown) is attached to a pull wire 124 that extends down from the mechanism. The mechanism is capable of raising and lowering the pull wire 124 and rotating the pull wire 124. The ingot puller 100 may have a pull shaft rather than a wire, depending upon the type of puller. The pull wire 124 terminates in a pulling assembly 126 that includes a seed crystal chuck 128 which holds a seed crystal 130 used to grow the silicon ingot. In growing the ingot, the pulling mechanism lowers the seed crystal 130 until it contacts the surface of the silicon melt 102. Once the seed crystal 130 begins to melt, the pulling mechanism slowly raises the seed crystal up through the growth chamber 108 and pull chamber 110 to grow the single crystal ingot. The speed at which the pulling mechanism rotates the seed crystal 130 and the speed at which the pulling mechanism raises the seed crystal (i.e., the pull rate v) are controlled by the control system. As the seed crystal 130 is slowly raised from the melt 102, silicon atoms from the melt 102 align themselves with and attach to the seed crystal 130 to form an ingot.

A process gas is introduced through the inlet port 114 into the housing 106 and is withdrawn from the outlet port 116. The process gas creates an atmosphere within the housing and the melt and atmosphere form a melt-gas interface. The outlet port 116 is in fluid communication with an exhaust system (not shown) of the ingot puller.

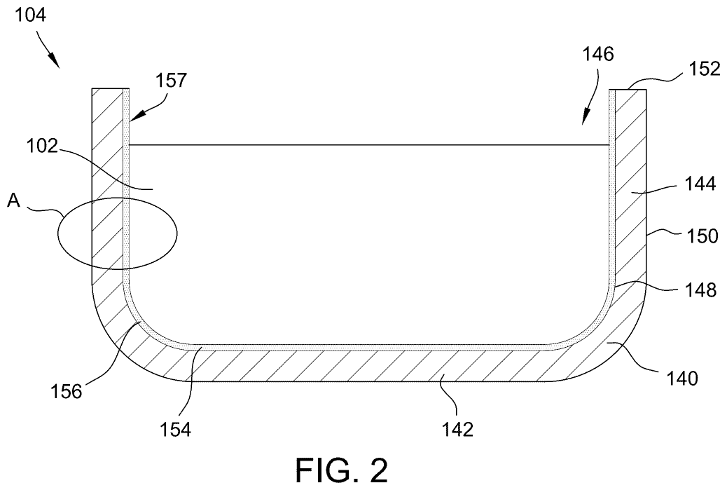

Referring to FIG. 2, the crucible 104 is schematically shown with a silicon melt 102 contained therein. The crucible 104 includes a body 140 that includes a bottom wall 142 and a sidewall 144 extending up from the bottom wall 142. The bottom wall 142 and sidewall 144 define a cavity 146 that receives the melt 102 therein. The body 140 further includes an inner surface 148 and an outer surface 150 extending along opposed sides of the bottom wall 142 and the sidewall 144. The sidewall 144 forms a rim 152 at a top of the crucible 104, which is open. The body 140 is formed of a natural silica material or quartz (terms used interchangeably herein).

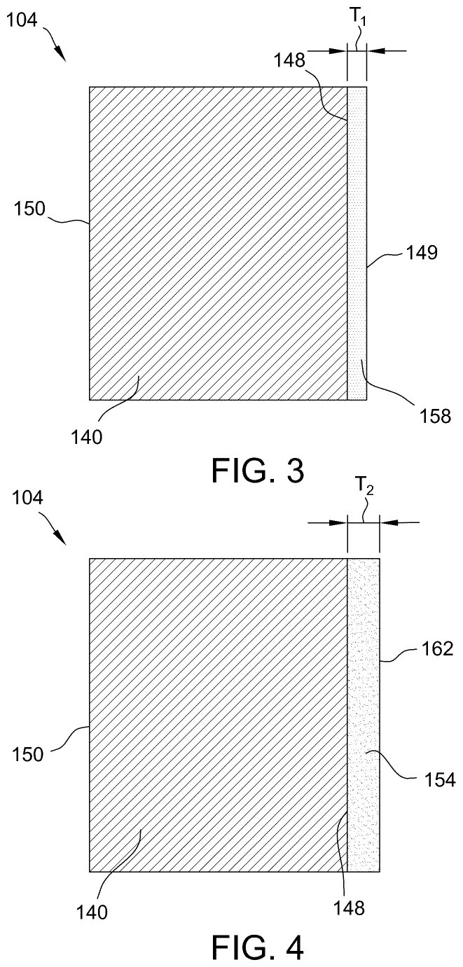

The crucible 104 further includes a crystallized layer 154 provided on the inner surface 148 of the body 140 and facing the melt 102. The crystallized layer 154 includes an unwetted portion 157 extending from the rim 152 to the surface of the melt 102 and a wetted portion 157 extending below the unwetted portion 157 and below the surface of the melt 102. The wetted portion 157 contacts the melt 102 during at least a portion of the ingot growth process while the unwetted portion 157 is out of contact with the melt 102. The crystallized layer 154 on the crucible 104 is formed from a devitrified synthetic liner 158 (shown in FIG. 3) provided on the inner surface 148 of the crucible 104. The immersion of the liner 158 in the melt 102 in the wetted portion 157 crystalizes the wetted portion 157 of the layer while the unwetted portion 157 of the layer 154 is not crystallized during the ingot growing process.

FIGS. 3 and 4 show an enlarged view of the region A (shown in FIG. 2) of the crucible 104. FIG. 3 shows the region A of the crucible 104 having a synthetic liner 158 prior to immersion of the liner in the melt 102. FIG. 4 shows the region A of the crucible 104 after the liner has been immersed in the melt 102 and devitrified to form the crystallized layer 154. The schematic proportions of the liner, the crystallized layer 154, and the crucible 104 are not shown to scale in the Figures. In particular, the thicknesses of the liner and the crystallized layer 154 are exaggerated in the Figures.

Referring to FIG. 3, the liner 158 is formed of synthetic silica and is also referred to as a “synthetic liner” herein. Table 1 below shows a chemical composition of the synthetic liner 158 in parts per million (“ppm”) as compared to a natural quartz or “natural sand” liner. As shown in Table 1, the synthetic liner 158 includes substantially reduced impurity concentrations relative to the natural liner.

TABLE 1
Example Impurity Compositions of Natural
Liner vs. Synthetic liner 158

| | Synthetic | Natural |
|---|---|---|
| Impurity (ppm) | liner 158 | Liner |
| Aluminum (Al) | 0.01 | 6.9 |
| Calcium (Ca) | 0.01 | 0.5 |
| Copper (Cu) | 0.01 | 0.05 |
| Iron (Fe) | 0.01 | 0.1 |
| Potassium (K) | 0.01 | 0.05 |
| Lithium (Li) | 0.01 | 0.15 |
| Sodium (Na) | 0.01 | 0.05 |
| Titanium (Ti) | 0.01 | 1.3 |
| Boron (B) | 0.01 | 0.04 |
| Magnesium (Mg) | 0.01 | 0.05 |
| Zinc (Zn) | 0.01 | 0.05 |
| Nickel (Ni) | 0.01 | 0.05 |
| Chromium (Cr) | 0.01 | 0.05 |

The liner 158 extends continuously along the inner surface 148 of the crucible 104 from the rim 152 and along the bottom wall 142, substantially covering the inner surface 148. In other embodiments, at least some portions of the body 140 surface, such as portions of the body 140 near unwetted portion 157, may not be covered by the liner. The crucible 104 is manufactured with the liner by an arc fusion process, though other suitable manufacturing processes for the crucible 104 such as plasma spraying, slip casting, or 3-D printing may be used.

The liner 158 is designed and adapted for a devitrification process at high temperatures, such that when, when the liner 158 is exposed to the high temperature melt 102, the melt 102 causes the liner 158 to crystalize, as shown in FIG. 4. To form the crystallized layer 154 (shown in FIG. 2), an initial charge of polysilicon is added to the crucible 104 and is melted to form the melt 102. Additionally, a melt modifier precursor is introduced into the crucible 104, before or after the polysilicon is melted. As the crucible 104 is heated the polysilicon is melted to form the silicon melt 102. The melt modifier precursor reacts with the melt 102, releasing waste gas and dissolving a melt modifier within the melt 102. The waste gas (e.g., carbon dioxide) is vented out of the crucible 104.

The melt modifier precursor is introduced into the melt 102 by use of a feed tube (not shown) that extends at least partially within the housing 106 (FIG. 1) and is positionable to allow the precursor to flow into the melt 102. In other embodiments, the melt modifier precursor and/or the melt modifier itself may be introduced into the melt 102 by a variety of different apparatuses and methods, such as, without limitation, by implanting the precursor into a cavity 146 of a seed that is immersed into the melt 102, by placing the precursor into a silicon carriage (not shown) that is then placed in the melt 102, by positioning a quartz trap door container containing the precursor therein over the melt 102 and opening the door to release the precursor into the melt 102.

The melt modifier reacts with the melt 102 such that the modified melt 102 (also referred to as “doped melt 102”) acts as a nucleating agent on the liner, which promotes devitrification of the synthetic liner 158 to form the crystallized layer 154. The silicon melt 102 is doped to a concentration about 0.013 milligrams of modifier per kilogram of silicon.

The melt 102 may be doped prior to each crystal growing operation or may be doped routinely depending on the Cz process used and whether the doping has an effect on crystal yield for the respective Cz process. For example, some Cz processes are less thermally aggressive and may not necessarily have to be doped each time between an initial crystal and subsequent crystals. For other Cz processes it can be beneficial to dope between initial crystal and subsequent crystals.

A suitable melt modifier is barium oxide (BaO). However, barium oxide is unstable at normal atmospheric temperatures and pressures. Specifically, at normal atmospheric temperatures and pressures barium oxide reacts with water (H₂O) and carbon dioxide (CO₂) in the atmosphere to form barium carbonate (BaCO₃). The application of heat to barium carbonate from the melt 102 decomposes barium carbonate back into barium oxide and carbon dioxide. Accordingly, the barium carbonate (also referred to as a “melt modifier precursor”) is introduced to the melt 102 and decomposes into the melt 102, releasing carbon dioxide (CO₂) and providing a concentration of the barium oxide (BaO) melt modifier within the melt 102.

The barium oxide may alternatively be maintained in an unreacted, pure state. For example, barium oxide may be stored and maintained in bottles that also include an inert gas within the bottle to minimize exposure to moisture, and steps may be taken to minimize air contact with the barium oxide when the barium oxide is transferred to the silicon melt 102. In further embodiments, other suitable melt modifier precursors may be used. Suitable melt modifier precursors may include any compound containing a suitable ion, such as Barium, Calcium, Strontium, Magnesium, and a suitable counter molecule that decomposes and delivers the ion into the melt 102 to allow for interaction of the ion with the glassy lining surface 149 (shown in FIG. 3) and mediate nucleation of cristobalite on the lining surface 149. Suitable counter molecules include for example, and without limitation, Oxygen, Carbonate, Oxalates, Fluorine, etc. Example suitable precursors include, without limitation, strontium carbonate (SrCO₃), calcium carbonate (CaCO₃), and/or magnesium carbonate (MgCO₃).

The liner has a starting thickness T₁ extending from the inner surface 148 of the crucible 104 quartz body 140 to a lining surface 149 that is positioned to contact the melt 102. The starting thickness T₁ of the liner is selected based on a desired resulting crystallized thickness T₂ of the crystallized layer 154 (shown in FIG. 4) after the liner is devitrified. For example, in the present embodiment, the starting thickness T₁ is less than 500 microns (um) to produce a resulting crystallized thickness T₂ of less than 700 microns (um). The concentration of the melt modifier in the doped melt 102 reacts with the synthetic liner 158 to promote devitrification of the synthetic liner 158 and produce a thin devitrified layer, as shown in FIG. 4.

Referring to FIG. 4, the liner is shown as a crystallized or “devitrified” layer (terms used interchangeably herein) after exposure to the doped melt 102. In particular, the silica liner is devitrified as cristobalite in the example embodiment from exposure to the modified melt 102. The crystallized layer 154 alters the equilibrium at the melt 102/crucible 104 boundary (i.e., the “cristobalite/silicon/glass phase boundary”) such that bubble nucleation is avoided, silicon melt 102 vibrations are reduced, and the resulting structure of the ingot is improved.

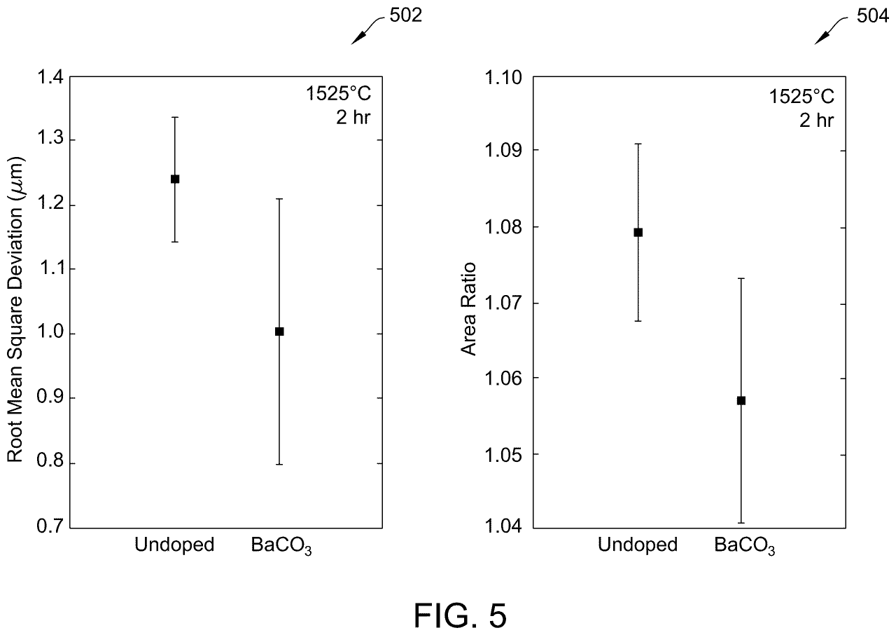

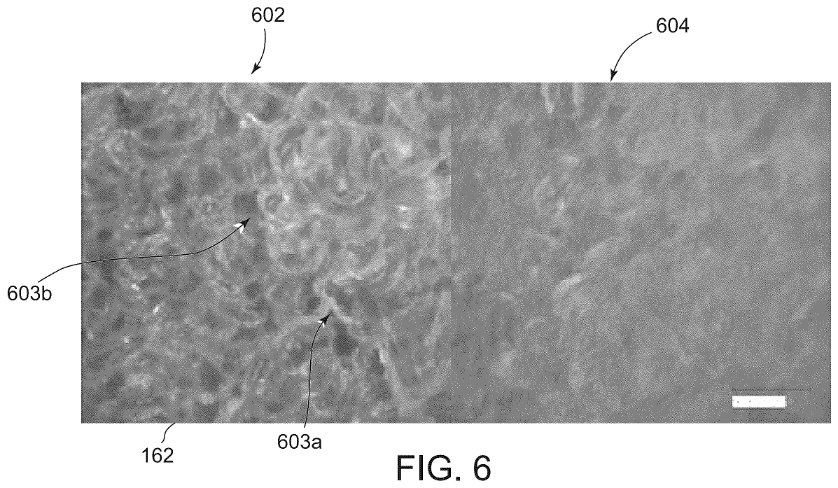

The crystallized layer 154 extends radially inward from the inner surface 148 of the quartz crucible 104 body 140 to a crystallized surface 162 which contacts the melt 102. In addition to promoting devitrification of the liner 158, the doped melt 102 also provides a reduced surface roughness of the crystallized surface 162 relative to an unmodified or “non-doped” melt 102, as described in greater detail with respect to FIGS. 5 and 6. The crystallized layer 154 defines a crystallized thickness T₂ between the inner surface 148 of body 140 and the lining surface 149. The crystallized thickness T₂ is increased relative to the starting thickness T₁ of the liner due to the devitrification of the liner. The crystallized thickness T₂ is less than or equal to 700 microns (um), less than or equal to 500 microns (um), or less than or equal to 100 microns (um). The crystallized thickness T₂ is preferably sufficiently thick to allow for the starting synthetic liner 158 to be continuous during the arc fusion process. In some embodiments, the crystallized thickness T₂ may be 50 microns (um).

The crystallized thickness T₂ being less than or equal 700 microns, at least in part, improves the resistance of the crystallized layer 154 to thermal spalling as compared with crystallized liners having a thickness that is greater than or equal to 700 microns. For example, experimental testing indicated that keeping the crystallized layer 154 thickness T₂ below 700 microns produced full bottom crystals, whereas using crucibles having a crystallized thickness T₂ in excess of 700 microns increased the potential for thermal spalling and resulted in a loss of dislocation structure in the crystals between approximately 65 to percent of the intended crystal body 140 length.

FIGS. 5 and 6 shows results from an example experiment demonstrating reduced surface roughness of the crystallized layer 154 using a doped melt 102 as compared to an undoped melt 102. The smoother surface roughness of the crystallized layer 154 is desirable because increased roughness in the crystallized layer 154 causes increased instabilities at the melt 102/crucible 104 boundary, which can cause damage the resulting ingot.

For example, the surface roughness of the crystallized surface 162 is correlated with a heat transfer coefficient of the crystallized layer 154. Additionally, the heat transfer coefficient of the crystallized layer 154 is correlated with bubble nucleation at the melt 102/crucible 104 boundary. In other words, as surface roughness of the crystallized layer 154 is increased, bubble nucleation at the melt 102/crucible 104 boundary is also increased. Thus, the surface roughness of the crystallized layer 154 can be understood as directly affecting the nucleating potential of the crystallized surface 162, with a smoother or less rough surface having reduced nucleation potential for a gas nucleating at the melt 102/crucible 104 boundary.

Bubble nucleation releases gas bubbles into the melt 102 which vibrate the melt 102 and can potentially damage the structure of the ingot. Additionally, bubble nucleation at the melt 102/crucible 104 boundary can also create microscopic voids in the silicon melt 102 which can persist into the grown ingot as the crystal ingot is formed. If present in the grown ingot these voids, also commonly referred to as “air pockets” or “pinholes,” weaken the resulting ingot structure and may even render the ingot unsuitable for use in electronic devices.

In the experiment, quartz samples having synthetic silica lined surfaces having a thickness of greater than or equal to two millimeters (mm) were each immersed in silicon melts 102 at a temperature of 1525 degrees Celsius for a two-hour immersion time. In a control test, the melt 102 was undoped, meaning that the melt 102 contained silicon and no nucleating agent melt modifiers were used. In a second test, the melt 102 was doped to about 0.013 milligrams of BaO per kilogram of silicon. The control test produced an undoped quartz sample and the second test produced a doped quartz sample. The samples were each removed from the melt 102 after two hours of immersion and were photographed and measured to compare the resulting surface roughness between the melts.

Referring to FIG. 5, a first chart, indicated at 502, shows a comparison of the root mean square (RMS) deviation in microns between the doped sample (indicated at BaCO3) and the undoped sample. A second chart, indicated at 504, shows a comparison of area ratio between the doped and undoped samples. The area ratio was determined by measuring the area over the peaks and valleys on the crystallized surfaces and normalizing the measurements to the area of the plan view.

As shown in the first chart, the doped sample had a reduced RMS deviation compared to the doped sample. Specifically, the doped sample had an RMS deviation of about 1 micron with detected deviations spanning between 0.8 and 1.2 microns. In comparison, the undoped sample had an RMS deviation of about 1.24 microns, with deviations ranging between about 1.15 and about 1.35. Additionally, as shown in the second chart, the doped sample also had a reduced area ratio relative to the undoped sample. In particular, the doped sample had an area ratio of about 1.0575, whereas the undoped sample had an area ratio of about 1.08. Thus, the undoped sample was found to have greater differences and between surface valleys and peaks as compared to the doped sample.

FIG. 6 shows microscopic photographs taken of the undoped sample, indicated at 602, and the doped sample, indicated at 604, after they were removed from the melt 102. The doped sample 602 had a visibly decreased roughness relative to the undoped sample 604. For example, as shown in the photos, the undoped sample photo showed more aggressive swirling features, as shown for example at 603a, and 603b, on the crystallized surface 162 consistent with more dramatic peaks and valleys. In contrast, the imaging of the doped sample shows a much more monotone and consistent crystallized surface 162, indicating a decreased surface roughness.

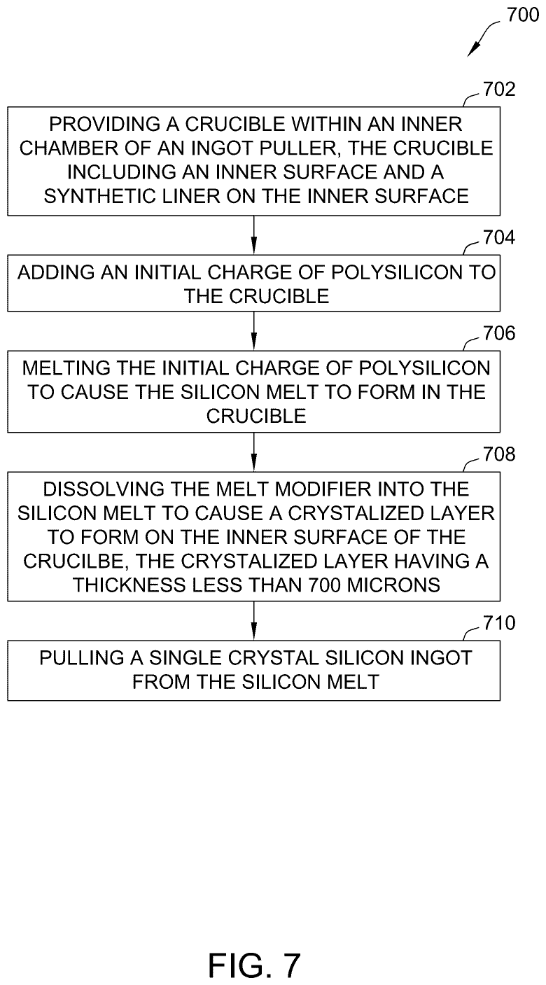

FIG. 7 is a flow diagram of a method 700 for producing a single crystal silicon ingot from a silicon melt 102 held within a crucible 104 positioned within an ingot puller apparatus. The method includes providing 702 a crucible 104 within an inner chamber of an ingot puller, the crucible 104 including an inner surface 148 and a synthetic liner 158 on the inner surface 148. The method further includes adding 704 an initial charge of polysilicon to the crucible 104. The method also includes melting 706 the initial charge of polysilicon to cause the silicon melt 102 to form in the crucible 104. The method further includes dissolving 708 a melt modifier into the silicon melt 102 to devitrify the synthetic liner 158 and form a crystallized layer 154 on the crucible 104, the crystallized layer 154 having a thickness T₂ less than 700 microns. The method also includes pulling 710 a single crystal silicon ingot from the silicon melt 102.

Advantages of using a synthetic liner 158 having a reduced thickness in combination with a melt 102 dosed to with high concentration of a nucleating agent, as described herein, include an improved resistance to thermal spalling of the crystallized layer 154. As a result, the crucible 104 may be exposed to the silicon melt 102 for longer continuous periods or added hot hours, which results in a cost reduction and an increased throughput and yield. As the throughput and yield are increased, the ingot is produced more efficiently and at less cost. Additional advantages include a reduced surface roughness of the crystallized surface 162 which reduces bubble nucleation in the melt 102, thereby improving the resulting structure and reducing defects in the grown crystal ingot.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for producing a single crystal silicon ingot from a silicon melt held within a crucible positioned within an ingot puller apparatus, the method comprising:
providing the crucible within an inner chamber of the ingot puller, the crucible including an inner surface and a synthetic liner on the inner surface;
adding an initial charge of polysilicon to the crucible;
melting the initial charge of polysilicon to cause the silicon melt to form in the crucible;
dissolving a melt modifier into the silicon melt to devitrify the synthetic liner and form a crystallized layer on the crucible, the crystallized layer having a thickness less than 700 microns; and
pulling a single crystal silicon ingot from the silicon melt.

2. The method of claim 1, wherein the synthetic liner has a first thickness and wherein the thickness of the crystalized layer is greater than the first thickness.

3. The method of claim 1, wherein the crucible includes a body having a bottom wall and a sidewall extending from the bottom wall to define a cavity within the body of the crucible, the inner surface extending along the bottom wall and the sidewall, wherein the synthetic liner extends continuously across the sidewall and bottom wall to substantially cover the inner surface of the body.

4. The method of claim 1, wherein the synthetic liner includes a synthetic silica material.

5. The method of claim 1 further comprising forming the crucible with the synthetic liner by an arc fusion process.

6. The method of claim 1 further comprising adding the melt modifier to the melt by a feed tube.

7. The method of claim 1, wherein dissolving the melt modifier dopes the melt to include a concentration of about 0.013 milligrams of melt modifier per kilogram of silicon.

8. The method of claim 1, wherein the method further includes:
adding a melt modifier precursor into the crucible;
forming the melt modifier by decomposing the melt modifier precursor in the melt; and
venting waste gas released from the decomposing out of the crucible.

9. The method of claim 8, wherein the melt modifier precursor is barium carbonate and wherein the melt modifier is barium oxide.

10. The method of claim 1 further comprising
selecting a starting thickness of the synthetic liner based on a desired end thickness of the crystalized layer; and
forming the synthetic liner on the crucible to have the starting thickness.

11. The method of claim 10, wherein the starting thickness is less than 500 microns.

12. A crucible for use with an ingot puller apparatus, the crucible comprising:
a body having an inner surface and an opposed outer surface; and
a synthetic liner provided on the inner surface of the body, the synthetic liner having a composition that devitrifies when exposed to a silicon melt to form a crystallized layer on the crucible during a crystal growing operation, the crystallized layer having a thickness less than 700 microns.

13. The crucible of claim 12, wherein the synthetic liner has a first thickness and wherein the thickness of the crystalized layer is greater than the first thickness.

14. The crucible of claim 12, wherein the crucible includes a body having a bottom wall and a sidewall extending from the bottom wall to define a cavity within the body of the crucible, the inner surface extending along the bottom wall and the sidewall, wherein the synthetic liner extends continuously across the sidewall and bottom wall to substantially cover the inner surface of the body.

15. The crucible of claim 12, wherein the synthetic liner includes a synthetic silica material.

16. The crucible of claim 12, wherein the synthetic liner has a thickness less than 500 microns.

17. A method for producing a single crystal silicon ingot from a silicon melt held within a crucible, the method comprising:
providing the crucible within an inner chamber of an ingot puller, the crucible including an inner surface and a synthetic liner on the inner surface;
adding an initial charge of polysilicon to the crucible;
adding a melt modifier precursor to the crucible;
melting the initial charge of polysilicon to cause the silicon melt to form in the crucible; and
dissolving the melt modifier precursor in the silicon melt to release a concentration of melt modifier into the silicon melt, the concentration of melt modifier devitrifying the synthetic liner and form a crystallized layer on the crucible, the crystallized layer having a thickness less than 700 microns.

18. The method of claim 17, wherein the synthetic liner has a first thickness and wherein the thickness of the crystalized layer is greater than the first thickness.

19. The method of claim 17, wherein the crucible includes a body having a bottom wall and a sidewall extending from the bottom wall to define a cavity within the body of the crucible, the inner surface extending along the bottom wall and the sidewall, wherein the synthetic liner extends continuously across the sidewall and bottom wall to substantially cover the inner surface of the body.

20. The method of claim 17, wherein the synthetic liner includes a synthetic silica material.
